(19) United States
(12) Patent Application Publication
(10) Pub. No.: US 2016/0254357 A1
(43) Pub. Date: Sep. 1, 2016

(54) SEMICONDUCTOR DEVICE AND SEMICONDUCTOR PACKAGE

(71) Applicant: ROHM CO., LTD., Kyoto-shi, Kyoto (JP)

(72) Inventor: Masatoshi AKETA, Kyoto-shi, Kyoto (JP)

(21) Appl. No.: 15/031,176

(22) PCT Filed: Oct. 24, 2014
(86) PCT No.: PCT/JP2014/078393

§ 371 Date: Apr. 21, 2016

(30) Foreign Application Priority Data
Oct. 24, 2013 (JP) 2013-221532

(51) Int. Cl. H01L 29/16; H01L 29/06; H01L 29/872; H01L 29/08; H01L 29/10; H01L 29/47; H01L 29/78; H01L 23/00; H01L 23/31; H01L 29/167; H01L 29/36; H01L 29/45; H01L 29/04; H01L 29/423

(52) U.S. Cl. CPC H01L 29/1608; H01L 29/045; H01L 29/0619; H01L 29/872; H01L 29/0865; H01L 29/1033; H01L 29/0882; H01L 29/4236; H01L 29/7811; H01L 29/7813; H01L 24/48; H01L 23/3107; H01L 24/85; H01L 24/32; H01L 24/73; H01L 29/0696; H01L 29/167; H01L 29/36; H01L 29/1095; H01L 29/45; H01L 29/47; H01L 2224/85206; H01L 2224/73265; H01L 2224/48091; H01L 2224/48247; H01L 2924/10272; H01L 2924/12032; H01L 2924/13091; H01L 2224/32245; H01L 2924/01007; H01L 2924/01015; H01L 2924/01033; H01L 2924/01005; H01L 2924/01013; H01L 2924/01022; H01L 2924/01028; H01L 2924/01047; H01L 2924/01079

(57) ABSTRACT

A semiconductor device of the present invention includes a semiconductor layer that has an off-angle inclined in a predetermined off-direction and that is made of a first conductivity type wide bandgap semiconductor at a surface of which a trench is formed, a first electrode bonded to a surface of the semiconductor layer, and a second electrode bonded to a back surface of the semiconductor layer, and when a side surface of the trench is decomposed into a parallel component and a perpendicular component with respect to the off-direction of the semiconductor layer, the parallel component is larger than the perpendicular component.

### TECHNICAL FIELD

The present invention relates to a semiconductor device which employs a wideband gap semiconductor and a semiconductor package including the semiconductor device.

### BACKGROUND ART

Attention has heretofore been paid to semiconductor power devices that are used chiefly in systems, such as motor control systems and power conversion systems, in various power electronics fields. A SiC Schottky barrier diode is publicly known as the semiconductor power device (see Patent Document 1, for example).

### CITATION LIST

### Patent Documents

Patent Document 1: Japanese Patent Application Publication No. 2005-79339

### SUMMARY OF INVENTION

### Solution to Problem

An embodiment of the present invention provides a semiconductor device including a semiconductor layer that has an off-angle inclined in a predetermined off-direction and that is made of a first conductivity type wide bandgap semiconductor at a surface of which a trench is formed, a first electrode bonded to a surface of the semiconductor layer, and a second electrode bonded to a back surface of the semiconductor layer, in which when a side surface of the trench is decomposed into a parallel component and a perpendicular component with respect to the off-direction of the semiconductor layer, the parallel component is larger than the perpendicular component.

According to this arrangement, the impact ionization coefficient of the wide bandgap semiconductor has anisotropy that it is different depending on the crystal orientation. Therefore, by making the parallel component of the side surface of the trench larger than the perpendicular component, the dielectric breakdown field strength in the trench portion can be increased, which allows an improvement in breakdown voltage. On the other hand, the mobility is relatively small in crystal orientation-dependent anisotropy. Therefore, when the side surface of the trench is formed as above to be improved in breakdown voltage, the influence on the mobility is small.

The semiconductor layer may have an off-angle of 0.1° to 10°. More specifically, the semiconductor layer may have an off-angle of 2° or more when the semiconductor layer is made of 4H—SiC having the surface being a Si plane, and may have an off-angle of 0.6° or more when the semiconductor layer is made of 4H—SiC having the surface being a C plane.

This allows an improvement in controllability in epitaxial growth of the semiconductor layer.

The off-direction may be a [11-20] axis direction or a [1-100] axis direction.

The trench may be formed in a stripe shape extending in a direction parallel to the off-direction.

According to this arrangement, the greater portion of the side surface of the trench is the parallel component with respect to the off-direction, which thus allows a more effective improvement in breakdown voltage.

An embodiment of the present invention includes a second conductivity type terminal structure formed at a surface of the semiconductor layer adjacent to a terminal of the first electrode.

The effect of an improvement in breakdown voltage of the trench portion described above is more effective when dielectric breakdown is likely to predominantly occur in the trench portion. In other words, because the measure against breakdown voltage of providing the terminal structure (voltage resistant structure) to generate a depletion layer due to pn junction is taken in the vicinity of the terminal of the first electrode where it is generally said that electric-field concentration is likely to occur, the breakdown voltage of the trench portion is likely to become relatively lower than that of the terminal portion.

The semiconductor layer may include an active region and an outer peripheral region that surrounds the active region and that is formed with a removal region in a surface portion of the semiconductor layer, and the terminal structure may be formed along a bottom surface of the removal region.

This arrangement makes it possible to prevent equipotential surfaces from densely gathering between the trench and the removal region by means of a depletion layer generated from a pn junction portion of an interface between the terminal structure and a drift layer. This makes it possible to relax electric-field concentration in the bottom of the trench.

An embodiment of the present invention further includes a second conductivity type layer that is formed in an inner area of the terminal structure and that is higher in concentration than the terminal structure.

This arrangement makes it possible to effectively relax electric-field concentration at the surface of the semiconductor layer.

The second conductivity type layer may include a highly-concentrated region that is formed so as to be exposed to the surface of the semiconductor layer and that is higher in concentration than the second conductivity type layer.

In an embodiment of the present invention, an edge of the terminal structure, an edge of the first electrode, and an edge of the second conductivity type layer are disposed in this order from an end surface of the semiconductor layer.

This arrangement makes it possible to further improve the semiconductor device in breakdown voltage.

An embodiment of the present invention further includes a second conductivity type guard ring formed on an outer side toward an end surface of the semiconductor layer with respect to the terminal structure.

An embodiment of the present invention includes a field insulating film formed from an edge of the terminal structure so as to selectively cover the terminal structure.

In an embodiment of the present invention, when a contact hole for the first electrode joining the surface of the semiconductor layer is formed in the field insulating film, the contact hole is formed in a tapered shape whose width becomes wider toward an opening end.

This arrangement makes it possible to further improve the semiconductor device in breakdown voltage.

In an embodiment of the present invention, the trench is formed as a plurality of mutually spaced trenches when the semiconductor layer is viewed cross-sectionally, and the plurality of trenches adjoining each other have a spacing of 0.1 μm to 10 μm therebetween.

The effect of an improvement in breakdown voltage of the trench portion described above is more effective when dielectric breakdown is likely to predominantly occur in the trench portion. In other words, because the trenches have a relatively wide spacing therebetween and equipotential surfaces are likely to densely gather between the trenches, the breakdown voltage of the trench portion is likely to become relatively low.

An embodiment of the present invention includes a Schottky barrier diode for which the first electrode forms a Schottky junction between the surface of the semiconductor layer and the first electrode and the second electrode forms an ohmic contact between the back surface of the semiconductor layer and the second electrode.

An embodiment of the present invention includes a first conductivity type source region that is exposed to the surface of the semiconductor layer so as to form a part of the side surface of the trench, a second conductivity type channel region that is adjacent at a back surface side of the source region so as to form a part of the side surface of the trench, a first conductivity type drain region that is adjacent at a back surface side of the channel region so as to form a bottom surface of the trench, and a gate electrode that is embedded in the trench via a gate insulating film, and includes a field effect transistor for which the first electrode forms an ohmic contact between the source region and the first electrode and the second electrode forms an ohmic contact between the drain region and the second electrode.

An embodiment of the present invention provides a semiconductor package including the semiconductor device, a first terminal connected to the first electrode of the semiconductor device via a bonding wire, a second terminal on which the semiconductor device is die-bonded and which is connected to the second electrode, and a resin package that encapsulates the semiconductor device, the first terminal, and the second terminal, in which the bonding wire is bonded to the first electrode by applying ultrasonic vibration along a predetermined ultrasonic vibration direction, and the off-direction and the ultrasonic vibration direction create an angle of 30° or less therebetween.

According to this arrangement, the semiconductor device is provided, which thus makes it possible to provide a semiconductor package that is low in impact on various device properties and allows an improvement in breakdown voltage.

Additionally, in an embodiment of the present invention, the off-direction and the ultrasonic vibration direction are parallel to each other.

### BRIEF DESCRIPTION OF DRAWINGS

FIG. 1 is a schematic configuration view of a semiconductor package according to an embodiment of the present invention.

FIG. 2 is a schematic plan view of a Schottky barrier diode according to an embodiment of the present invention.

FIG. 3 is a cross-sectional view presented when the Schottky barrier diode is cut along a cutting line III-III in FIG. 2.

FIG. 4 is a schematic view showing a unit cell having a crystal structure of 4H—SiC.

FIG. 5 is a view of the unit cell of FIG. 4 viewed from directly above a (0001) plane.

FIGS. 6A and 6B are views to describe the plane orientation of a trench side surface, in which FIG. 6A is a main part enlarged view of a SiC epitaxial substrate, and FIG. 6B is a plan view of the Schottky barrier diode.

FIGS. 7A to 7C are other layout diagrams of the unit cells of FIG. 1.

FIG. 8 is a radar chart showing a relationship of the plane orientation and breakdown voltage of a trench side surface.

FIG. 9 is a view showing a modification of the Schottky barrier diode of FIG. 3.

FIG. 10 is a view showing a modification of the Schottky barrier diode of FIG. 3.

FIG. 11 is a view showing a modification of the Schottky barrier diode of FIG. 3.

FIG. 12 is a view showing a modification of the Schottky barrier diode of FIG. 3.

FIG. 13 is a view showing a modification of the Schottky barrier diode of FIG. 3.

FIG. 14 is a view showing a modification of the Schottky barrier diode of FIG. 3.

FIG. 15 is a view showing a modification of the Schottky barrier diode of FIG. 3.

FIG. 16 is a view showing a modification of the Schottky barrier diode of FIG. 3.

FIG. 17 is a view showing a modification of the Schottky barrier diode of FIG. 3.

FIG. 18 is a view showing a modification of the Schottky barrier diode of FIG. 3.

FIG. 19 is a view showing a modification of the Schottky barrier diode of FIG. 3.

FIG. 20A is a view to describe a method for forming a p type layer.

FIG. 20B is a cross-sectional view showing a step subsequent to that of FIG. 20A.

FIG. 21A is a view to describe a method for forming a p type layer.

FIG. 21B is a cross-sectional view showing a step subsequent to that of FIG. 21A.

FIG. 21C is a cross-sectional view showing a step subsequent to that of FIG. 21B.

FIG. 22 is a schematic cross-sectional view of a field effect transistor according to an embodiment of the present invention.

FIG. 23 is a schematic configuration view of a semiconductor package to describe a modification of the direction of ultrasonic vibration.

### DESCRIPTION OF EMBODIMENTS

Embodiments of the present invention will be hereinafter described in detail with reference to the accompanying drawings.

### <Configuration of Semiconductor Package 201>

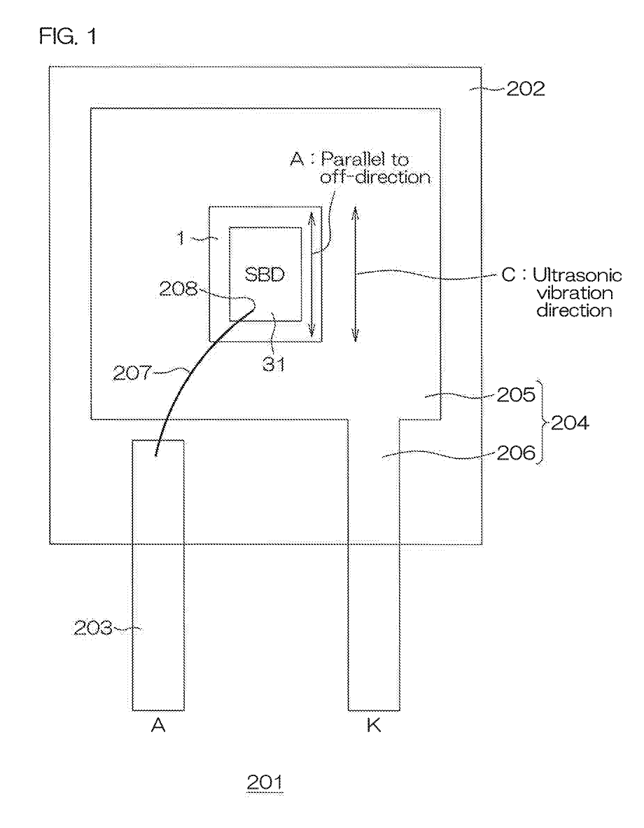

FIG. 1 is a schematic configuration view of a semiconductor package 201 according to an embodiment of the present invention.

The semiconductor package 201 includes a flattened rectangular parallelepiped resin package 202 and an anode terminal 203 (A) and a cathode terminal 204 (K) encapsulated in the resin package 202.

The two terminals 203 and 204 are each formed of a metal plate in a predetermined shape. In the present embodiment, the cathode terminal 204 is formed in a shape including a square island 205 and an elongated rectangular terminal portion 206 extending linearly from a side of the island 205. The anode terminal 203 is formed in approximately the same shape as that of the terminal portion 206 of the cathode terminal 204, and is disposed in parallel with the terminal portion 206 of the cathode terminal 204.

On the cathode terminal 204 (a central portion of the island 205), a Schottky barrier diode 1 is die-bonded. The island 205 is bonded from below to a cathode electrode 6 (described later) of the Schottky barrier diode 1.

The anode terminal 203 is connected to the Schottky barrier diode 1 using a bonding wire 207. The bonding wire 207 is bonded to the anode terminal 203 and an anode electrode 31 of the Schottky barrier diode 1 by application of ultrasonic vibration. When the bonding wire 207 is bonded, ultrasonic vibration is applied in a direction (C: ultrasonic vibration direction) parallel to an off-direction (described later) of an n type substrate 2. That is, in the present embodiment, ultrasonic vibration is applied along a stripe direction of trenches 13 (described later). Whether the ultrasonic vibration is being applied in the same direction can be confirmed by, for example, observing the shape of splashes formed on the anode electrode 31 through an electronic microscope or the like. In the present embodiment, on the surface of the anode electrode 31 after bonding of the bonding wire 207, the amount of splashes occurring to a bonding portion 208 of the bonding wire 207 at its both sides along a direction “A: parallel to the off-direction” becomes relatively large.

### <Configuration of Schottky Barrier Diode 1>

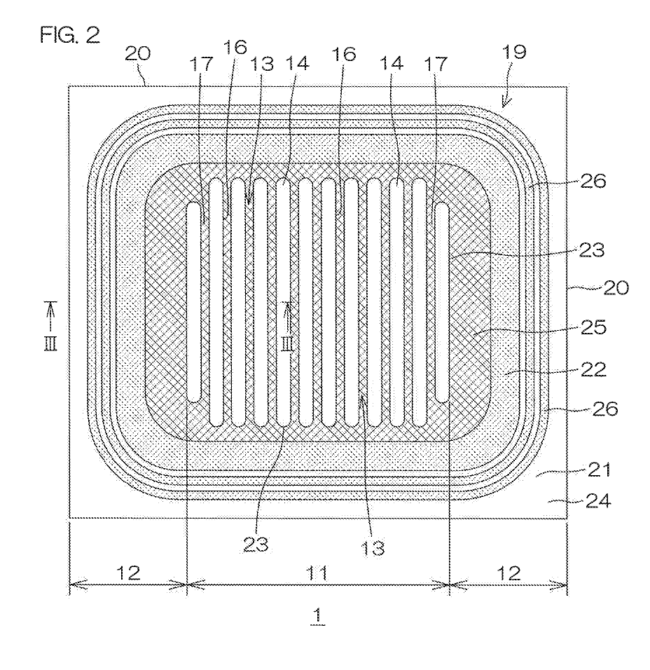

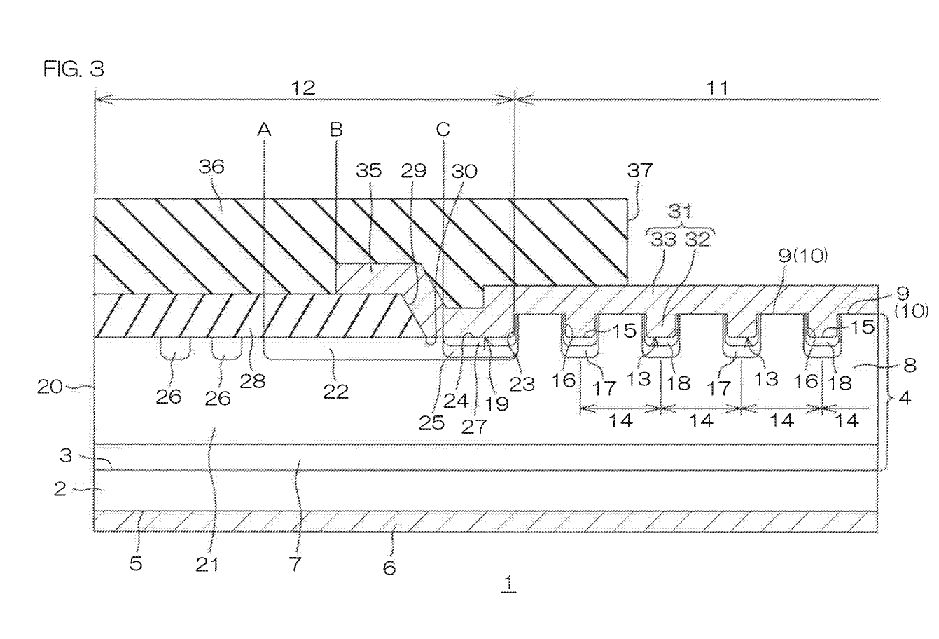

FIG. 2 is a schematic plan view of a Schottky barrier diode 1 according to an embodiment of the present invention. FIG. 3 is a cross-sectional view presented when the Schottky barrier diode 1 is cut along a cutting line III-III in FIG. 2.

The Schottky barrier diode 1 is a device that employs 4H—SiC (a wide bandgap semiconductor having a dielectric breakdown field strength of approximately 2.8 MV/cm and a bandgap width of approximately 3.26 eV). In addition, the wide bandgap semiconductor to be employed by the Schottky barrier diode 1 may be, for example, GaN, Ga₂O₃, diamond, etc., without being limited to SiC. GaN has its dielectric breakdown field strength of approximately 3 MV/cm and a bandgap width of approximately 3.42 eV. Ga₂O₃ has a bandgap width of approximately 4.8 eV. Diamond has its dielectric breakdown field strength of approximately 8 MV/cm and a bandgap width of approximately 5.47 eV.

The Schottky barrier diode 1 includes an n⁺ type substrate 2 made of n⁺ type SiC and an epitaxial layer 4 laminated on a surface 3 of the n⁺ type substrate 2. In the present embodiment, the n⁺ type substrate 2 and the epitaxial layer 4 are shown as an example of a semiconductor layer of the present invention. At a back surface 5 of the n⁺ type substrate 2, a cathode electrode 6 that is an example of a second electrode of the present invention is disposed in a manner covering its entire area. The cathode electrode 6 forms an ohmic contact between the n⁺ type substrates 2 and the cathode electrode 6. The cathode electrode 6 is to be bonded to the cathode terminal 204 (island 205) in the semiconductor package 201 (see FIG. 1).

The epitaxial layer 4 includes an n type buffer layer 7 and an n⁻ type drift layer 8 that are grown in order from the side of the n⁺ type substrate 2.

An active region 11 and an outer peripheral region 12 that surrounds the active region 11 are set on a surface of the epitaxial layer 4. In the active region 11, a plurality of mutually spaced trenches 13 are formed in the surface portion of the epitaxial layer 4.

The trenches 13 define a plurality of unit cells 14 in the active region 11. In the present embodiment, the trenches 13 having a stripe pattern define a plurality of line-shaped unit cells 14 in the active region 11 as shown in FIG. 2. As a result, the plurality of unit cells 14 are arranged in a stripe manner so as to be mutually equally spaced as shown in FIG. 2.

At a bottom surface 15 and a side surface 16 of each trench 13 (hereinafter, these surfaces are collectively referred to as “an inner surface of the trench 13” when necessary), a p type layer 17 (the cross-hatched area in FIG. 2 (excluding the area of a p type layer 25 to be described later)) is formed in a manner following the inner surface of the trench 13.

The p type layer 17 is, in the present embodiment, formed at the whole of the bottom surface 15 and the whole of the side surface 16 of the trench 13. Accordingly, the n⁻ type drift layer 8 is not exposed to the inner surface of the trench 13, and the p type layer 17 is exposed across the entire area from the bottom of the trench 13 to the surface 10 of the epitaxial layer 4. Therefore, around the trench 13, a pn junction portion of the p type layer 17 and the n⁻ type drift layer 8 is formed following the inner surface of the trench 13. In addition, the p type layer 17 may be selectively formed at only the bottom surface 15 of the trench 13 or may be selectively formed at only the side surface 16. Additionally, the p type layer 17 may be formed at the bottom surface 15 and the side surface 16 across the whole areas as in FIG. 3 or only in parts, respectively.

Additionally, the p type layer 17 includes a p type contact layer 18 that is higher in concentration than other parts of the p type layer 17 as shown in FIG. 3. In the inner area away from the boundary between the p type layer 17 and the n⁻ type drift layer 8, the p type contact layer 18 is formed at the bottom surface 15 and the side surface 16 of the trench 13 along that boundary. More specifically, the p⁺ type contact layer 18 is formed in an area that is shallower than the depth position of 1000 Å from the inner surface of the trench 13.

The p type layer 17 has mutually different thicknesses between the bottom surface 15 and the side surface 16 of the trench 13. More specifically, a part on the bottom surface 15 of the p type layer 17 is thicker than a part on the side surface 16. As a result, a difference in thickness of the p type layer 17 is provided between the bottom surface and the side surface 16. Likewise, concerning the p⁺ type contact layer 18 formed inside the p type layer 17, a difference in thickness is provided between the bottom surface 15 and the side surface 16.

In the outer peripheral region 12, a removal region 19 is formed in the epitaxial layer 4 by selectively etching the epitaxial layer 4. In the present embodiment, the removal region 19 is formed in an annular shape surrounding the active region 11 so as to cross both ends in the longitudinal direction of the stripe-patterned trenches 13. As a result, the removal region 19 connects to the stripe-patterned trenches 13. In other words, the removal region 19 is formed of an extension of the stripe-patterned trenches 13. An outer peripheral edge of the removal region 19 may coincide with an end surface 20 of the epitaxial layer 4 as shown in FIG. 2, or may be set inside the end surface 20 of the epitaxial layer 4 (not shown).

As a result of the formation of the removal region 19, the n⁻ type drift layer 8 has a drawer portion 21 that is drawn out from the periphery of the active region 11 to the end surface 20 of the epitaxial layer 4 in the lateral direction along the surface 10 of the epitaxial layer 4. The drawer portion 21 is a low stepped portion that is lower by one step than an upper surface 9 of the unit cells 14 as shown in FIG. 3.

In the outer peripheral region 12, a p type JTE (Junction Termination Extension) structure 22 that is an example of a terminal structure of the present invention and a plurality of guard rings 26 are formed in the n⁻ type drift layer 8. For the sake of clarification, the p type JTE structure 22 and the guard rings 26 are presented as dot-hatched areas in FIG. 2. In the present embodiment, the p type JTE structure 22 and the guard rings 26 are formed in this order from the side of the active region 11 in an annular shape surrounding the active region 11.

More specifically, the p type JTE structure 22 is formed so as to follow a side surface 23 and a bottom surface 24 (upper surface of the drawer portion 21) of the removal region 19. The guard rings 26 are formed so as to further surround the p type JTE structure 22. The p type JTE structure 22 may be formed so that the dopant concentration is constant over its entirety, or may be formed so that the dopant concentration becomes smaller toward the outside. The dopant concentration of the guard rings 26 may be the same as that of the p type JTE structure 22, or may be smaller than that of the p type JTE structure 22.

In the present embodiment, a p type layer 25 (the cross-hatched area in FIG. 1) that is an example of a second conductivity type layer of the present invention and that is relatively higher in concentration than the p type JTE structure 22 is formed in the p type JTE structure 22.

The p type layer 25 is formed so as to follow the side surface 23 and the bottom surface 24 (upper surface of the drawer portion 21) of the removal region 19. Additionally, the p type layer 25 is disposed at a position inwardly away from the outer periphery of the p type JTE structure 22. This makes it possible to effectively relax electric-field concentration at the surface 10 of the epitaxial layer 4 (the bottom surface 24 of the removal region 19).

A p⁺ type contact layer 27 that is an example of a highly-concentrated region of the present invention and that is higher in concentration than the p type layer 25 is formed in the p type layer 25. In the inner area away from the boundary between the p type JTE structure 22 and the n⁻ type drift layer 8, the p⁺ type contact layer 27 is formed at the side surface 23 and the bottom surface 24 of the removal region 19 along that boundary. More specifically, the p⁺ type contact layer 27 is formed in an area that is shallower than the depth position of 1000 Å from the inner surface of the removal region 19.

A field insulating film 28 is formed on the epitaxial layer 4. A contact hole 29 that selectively exposes the whole of the active region 11 and a part of the outer peripheral region 12 is formed in the field insulating film 28. In the present embodiment, an outer peripheral edge 30 of the contact hole 29 is set on the side farther from the active region 11 with respect to the boundary (p type layer edge C (outer peripheral edge of the p type layer 25)) between the p type layer 25 and the p type JTE structure 22. As a result, the field insulating film 28 selectively covers a part of the p type JTE structure 22, and exposes the whole of the p type layer 25. Preferably, the contact hole 29 is formed in a tapered shape whose width becomes wider toward its opening end.

An anode electrode 31 that is an example of a first electrode of the present invention is formed on the field insulating film 28. The anode electrode 31 is formed so as to cover the whole of the active region 11 exposed from the contact hole 29, and integrally includes an embedded portion 32 embedded in the trenches 13 and a planar portion 33 that is formed so as to cover the embedded portion 32 while following the surface 10 of the epitaxial layer 4.

The embedded portion 32 is in contact with the p⁺ type contact layer 18 at the inner surface of the trench 13, and forms an ohmic contact between the p⁺ type contact layer 18 and the embedded portion 32.

The planar portion 33 is in contact with the n⁻ type drift layer 8 at the upper surface 9 of the unit cell 14 (the surface 10 of the epitaxial layer 4), and forms a Schottky junction between the n⁻ type drift layer 8 and the planar portion 33. Additionally, the planar portion 33 projects in a flange shape outwardly from the contact hole 29, and rides on the field insulating film 28. In the present embodiment, the outer peripheral edge (electrode edge B) of the planar portion 33 of the anode electrode 31 is positioned on the side closer to the active region 11 with respect to the outer peripheral edge (JTE edge A) of the p type JTE structure 22, and is positioned on the side farther from the active region 11 with respect to the outer peripheral edge (p type layer edge C) of the p type layer 25. In other words, the positional relationship among these edges is the JTE edge A, the electrode edge B, and the p type layer edge C in order from the end surface 20 (outside). As a result, the planar portion 33 of the anode electrode 31 has an overlap portion 35 that bulges out toward the end surface beyond the p type layer edge C.

A surface protection film 36 is formed on the topmost surface of the Schottky barrier diode 1. A pad opening 37 that selectively exposes a part of the anode electrode 31 as a pad is formed in the surface protection film 36. The bonding wire 207 shown in FIG. 1 is bonded to the anode electrode 31 through the pad opening 37.

Details of each portion of the Schottky barrier diode 1 will be hereinafter described.

The Schottky barrier diode 1 is formed in a square chip shape when viewed planarly. Concerning its size, lengths in up, down, right, and left directions in the sheet of FIG. 2 are each 0.5 mm to 20 mm. In other words, the chip size of the Schottky barrier diode 1 is, for example, 0.5 mm/square to 20 mm/square.

The thickness of the n⁺ type substrate 2 is 50 μm to 700 μm, the thickness of the n type buffer layer 7 is 0.1 μm to 10 μm, and the thickness of the n⁻ type drift layer 8 is 2 μm to 100 μm.

For example, N (nitrogen), P (phosphorus), As (arsenic), etc., can be used as an n type dopant for use in each portion of the Schottky barrier diode 1 (the same applies hereinafter). On the other hand, for example, B (boron), Al (aluminum), etc., can be used as a p type dopant.

The dopant concentration of the n⁺ type substrate 2 is 1×10¹⁸ to 1×10²⁰ cm⁻³, the dopant concentration of the n type buffer layer 7 is 1×10¹⁵ to 1×10¹⁶ cm⁻³, and the dopant concentration of the n⁻ type drift layer 8 may be 1×10¹⁴ to 1×10¹⁷ cm⁻³.

The dopant concentration of the p type layer 17 is 1×10¹⁷ to 1×10¹⁹ cm⁻³, and the dopant concentration of the p⁺ type contact layers 18 and 27 may be 1×10¹⁹ to 3×10²¹ cm⁻³.

The dopant concentration of the p type JTE structure 22 and the guard rings 26 may be 1×10¹⁶ to 1×10¹⁸ cm⁻³. The dopant concentration of the p type layer 25 may be 1×10¹⁶ to 1×10¹⁸ cm⁻³.

The center-to-center pitch between mutually adjoining trenches 13 may be, for example, 0.1 μm to 10 μm. The depth of the trenches 13 and the depth of the removal region 19 may be equal to each other.

For example, Ti/Ni/Au/Ag and so forth can be used as the material of the cathode electrode 6.

For example, Ti/Al and so forth can be used as the material of the anode electrode 31.

For example, SiO₂ (silicon oxide), SiN (silicon nitride), and so forth can be used as the material of the field insulating film 28. The field insulating film 28 can be made according to, for example, a plasma CVD. Its film thickness can be set at 0.5 μm to 3 μm.

For example, SiO₂ (silicon oxide), SiN (silicon nitride), polyimide, and so forth can be used as the material of the surface protection film 36. The surface protection film 36 can be made according to, for example, the plasma CVD. Its film thickness may be set at about 8000 Å.

### <Plane Orientation (Crystal Orientation) of Side Surface 16 of Trench 13>

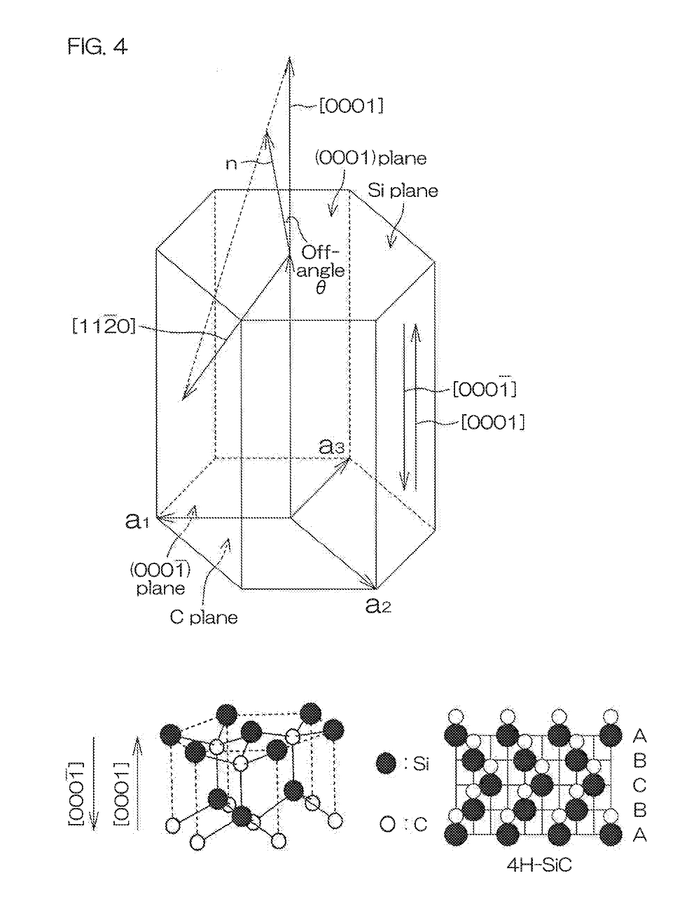

FIG. 4 is a schematic view showing a unit cell having a crystal structure of 4H—SiC. Concerning a perspective view of a SiC crystal structure shown in the lower part of FIG. 4, only two layers of the four layers of a SiC layered structure shown next to it are taken out and are shown there.

As shown in FIG. 4, the 4H—SiC crystal structure can be approximated in a hexagonal system, and four carbon atoms are bonded to a single silicon atom. The four carbon atoms are positioned at four vertexes of a regular tetrahedron in which the silicon atom is disposed in the center. Concerning these four carbon atoms, a single silicon atom is positioned in the direction of a [0001] axis with respect to a carbon atom, and the other three carbon atoms are positioned on the [000-1] axis side with respect to the silicon atom.

The [0001] axis and the [000-1] axis extend along the axial direction of a hexagonal prism, and the plane (top surface of the hexagonal prism) that defines this [0001] axis as a normal is a (0001) plane (Si plane). On the other hand, the plane (undersurface of the hexagonal prism) that defines the [000-1] axis as a normal is a (000-1) plane (C plane).

Directions that are perpendicular to the [0001] axis and that pass through vertexes of the hexagonal prism which do not mutually adjoin when seen from immediately above the (0001) plane are an a₁ axis [2-1-10], an a₂ axis [−12-10], and an a₃ axis [−1-120], respectively.

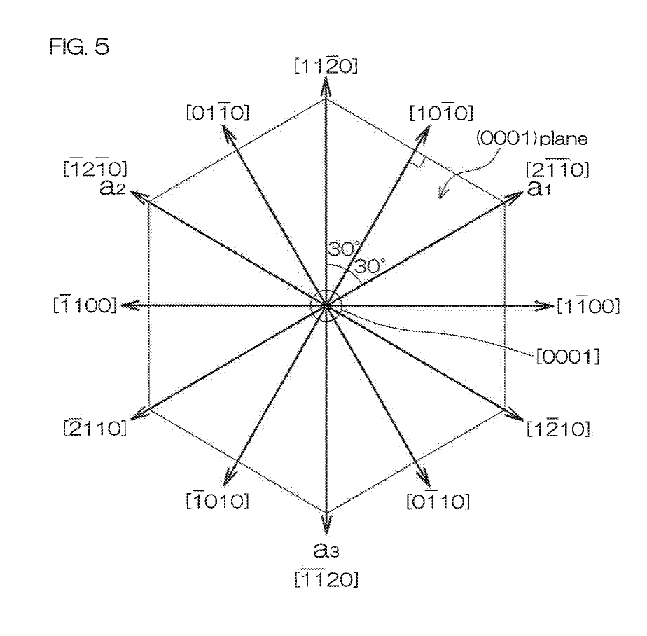

FIG. 5 is a view of the unit cell of FIG. 4 viewed from directly above the (0001) plane.

As shown in FIG. 5, the direction passing through the vertex between the as axis and the ax axis is a [11-20] axis, and the direction passing through the vertex between the a₂ axis and the a₃ axis is a [−2110] axis, and the direction passing through the vertex between the a₃ axis and the a₁ axis is a [1-210] axis.

Axes each of which is inclined at an angle of 30° with respect to each axis on the both sides in each space between the six axes respectively passing through the vertexes of the hexagonal prism and that is defined as a normal of each side surface of the hexagonal prism are a [10-10] axis, a [1-100] axis, a [0-110] axis, a [−1010] axis, a [−1100] axis, and a [01-10] axis, respectively, in the order of the clockwise direction from between the a₁ axis and the [11-20] axis. Each plane (side surface of the hexagonal prism) that defines each of these axes as a normal is a crystal plane perpendicular to the (0001) plane and to the (000-1) plane.

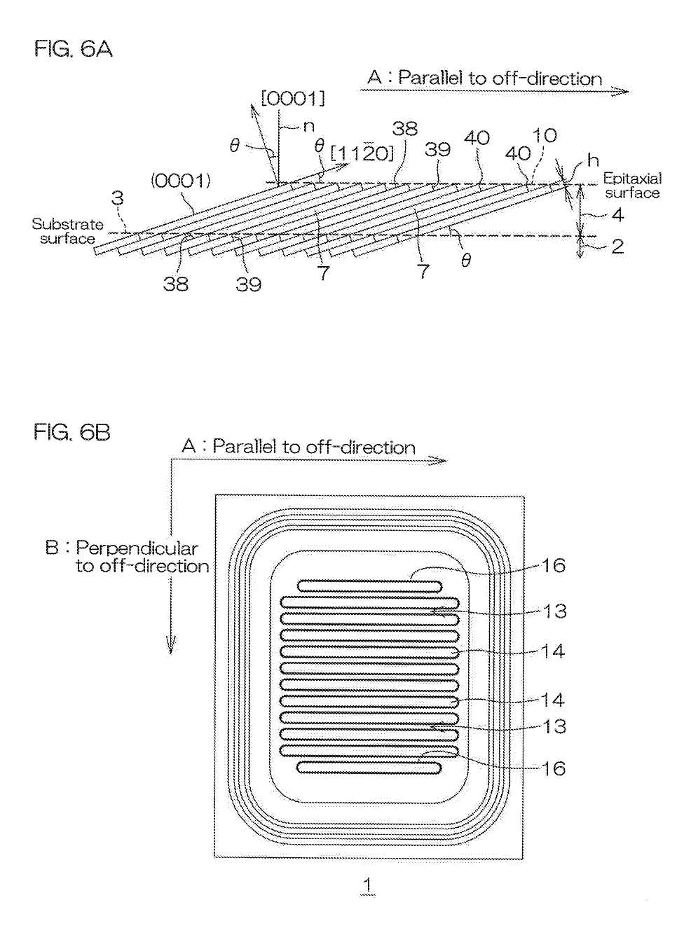

FIGS. 6A and 6B are views to describe the plane orientation of the side surface 16 of the trench 13, in which FIG. 6A is a main part enlarged view of a SiC epitaxial substrate (the n⁺ type substrate 2 and the epitaxial layer 4), and FIG. 6B is a plan view of the Schottky barrier diode 1.

As shown in FIG. 6A, the surface 3 of the n⁺ type substrate 2 has its normal n whose direction does not coincide with the direction of the [0001] axis, and is inclined at an off-angle θ of 2° or more in an off-direction of the [11-20] axis with respect to the (0001) plane. The off-direction denotes a direction in which the normal n of the n⁺ type substrate 2 is inclined with respect to the [0001] axis as shown in FIG. 4, and is shown by the direction of a vector in which the normal n is projected (is cast) from the [0001] axis to the (0001) plane. In other words, in the present embodiment, the direction of a projected vector of the normal n coincides with the [11-20] axis.

As a result, the n⁺ type substrate 2 is formed of a flat terrace plane 38 consisting of the (0001) plane and a stepped part of the terrace plane 38 that is generated by the inclination (off-angle θ) of the surface 3 with respect to the (0001) plane, and the stepped part has a step plane 39 that is a (11-20) plane perpendicular to the [11-20] axis. The height of the stepped part (step height h) corresponds to a Si—C pair layer 7 (bi-layer) for which carbon atoms are bonded onto a single silicon atom.

As shown in FIG. 6A, the step planes 39 of the respective layers 7 are aligned regularly while maintaining the width of the terrace planes 38 in the direction of the [11-20] axis. Also, step lines 40, which are step edges of the step planes 39, are aligned in parallel while taking on the width of the terrace planes 38 while maintaining a perpendicular relationship with the [11-20] axis direction (in other words, while maintaining a parallel relationship with respect to the direction of the [−1100] axis).

The epitaxial layer 4 is formed by the respective layers 7 undergoing crystal growth laterally along the [11-20] axis direction while maintaining the terrace planes 38 and the step planes 39 of the n⁺ type substrate 2. The off-angle θ of the n⁺ type substrate 2 is preferably 2° to 10°. If the off-angle θ is in this range, the step growth width (width of each layer 7 in the growth direction) can be made almost fixed, which thus allows an improvement in controllability in mass production of SiC epitaxial wafers (n⁺ type substrates 2 and epitaxial layers 4).

In the present embodiment, the trenches 13 are formed in a stripe shape extending in the direction parallel to the off-direction of the n type substrate 2 as shown in FIG. 6B. As a result, when the side surface 16 of the trench 13 is decomposed into a component “A: parallel to the off-direction” and a component “B: perpendicular to the off-direction,” the greater portion of the side surface 16 is the parallel component. As a result, the dielectric breakdown field strength in the trench 13 can be increased, which allows an improvement in breakdown voltage.

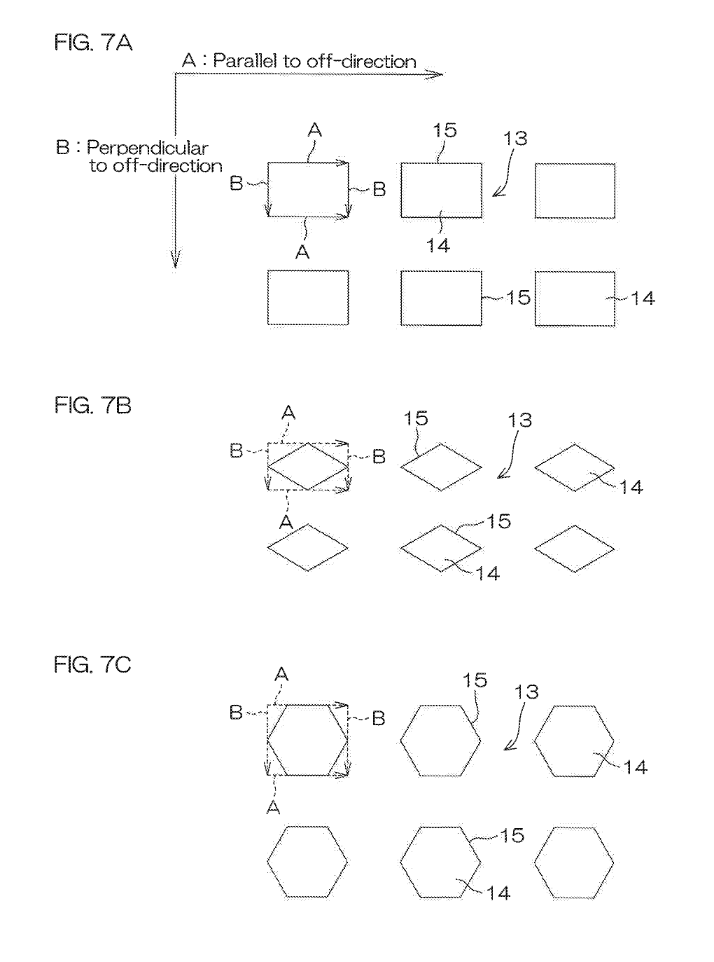

In addition, trenches 13 where the parallel component is larger than the perpendicular component when the side surface 16 is decomposed into a component “A: parallel to the off-direction” and a component “B: perpendicular to the off-direction,” may be in the shapes shown in FIG. 7A to FIG. 7C, besides the stripe shape in FIG. 6B. In other words, the unit cells 14 defined by the trenches 13 shown in FIG. 7A to FIG. 7C are, respectively, in oblong shapes having long sides that are “A: parallel to the off-direction,” rhomboid shapes having long axes that are “A: parallel to the off-direction,” and regular hexagonal shapes having opposite sides that are “A: parallel to off-direction.” In any of these shapes, when the side surface 16 is decomposed into a parallel component A and a perpendicular component B, the parallel component A is larger than the perpendicular component B.

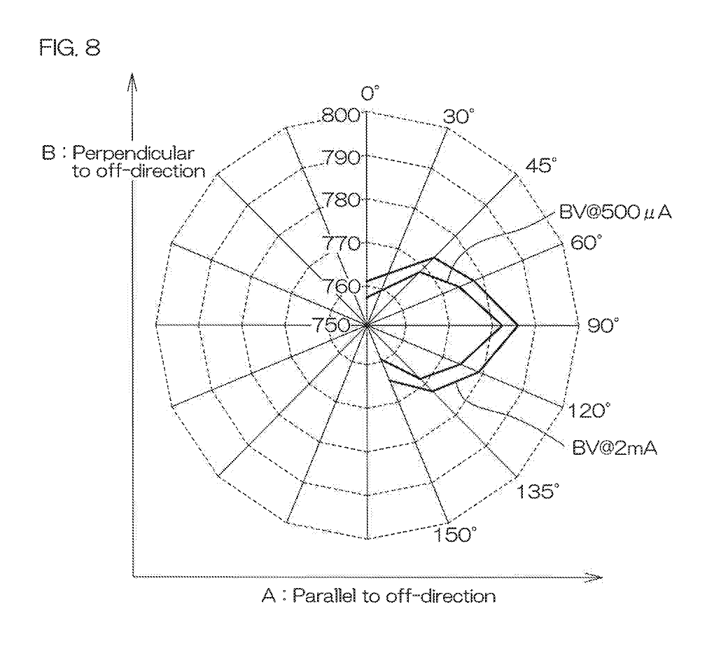

Moreover, the effect of an improvement in breakdown voltage brought about by satisfying that the parallel component A is larger than the perpendicular component B can be proved by FIG. 8.

FIG. 8 is a radar chart showing a relationship of the plane orientation and breakdown voltage of the side surface 16 of the trench 13. In FIG. 8, the figures representing angles placed on the outer periphery of the radar chart show what angle an experimental object trench 13 is inclined in the clockwise direction with respect to a reference trench 13 with an angle 0° that is “B: perpendicular to the off-direction.” In this case, the trench 13 with an angle “90°” corresponds to a trench that is “A: parallel to the off-direction.” On the other hand, the figures placed by tens in the radial direction of the radar chart show the breakdown voltage (BV) of the Schottky barrier diode 1.

It can be understood from FIG. 8 that the closer the angle of the trench 13 to 90° and the larger the parallel component A of the side surface 16 than the perpendicular component B, the greater the improvement in breakdown voltage. For example, in the case of an applied current of 500 μA, the breakdown voltage when the trench 13 is of a stripe that is “B: perpendicular to the off-direction” (0°) is approximately 760 V, while with the increase in the parallel component A to “45°” and “60°,” the breakdown voltages also increase to approximately 773 V and approximately 777 V, respectively. With the stripe trench 13 shown by “90°” that is “A: parallel to the off-direction,” the breakdown voltage is approximately 785 V.

The reason that the breakdown voltage is thus different depending on the crystal orientation of the side surface 16 is considered to be because the impact ionization coefficient of SiC has anisotropy that it is different depending on the direction “A: parallel to the off-direction” or “B: perpendicular to the off-direction.” In other words, because SiC has a small impact ionization coefficient at a crystal plane “A: parallel to the off-direction,” by increasing the ratio of the crystal plane in this direction, the dielectric breakdown field strength can be increased, which allows an improvement in breakdown voltage. On the other hand, the mobility in SiC is relatively small in crystal orientation-dependent anisotropy. Therefore, when the side surface 16 of the trench 13 is formed as above to be improved in breakdown voltage, the influence on the mobility is small.

Particularly, the effect of an improvement in breakdown voltage described above is more effective when dielectric breakdown is likely to predominantly occur in the trenches 13 as in the present embodiment. In other words, because the measure is taken against breakdown voltage by the p type JTE structure 22 to generate a depletion layer due to pn junction provided in the vicinity of the terminal of a surface electrode (in the present embodiment, the anode electrode 31) where it is generally said that electric-field concentration is likely to occur and the trenches 13 have a relatively wide spacing (3 μm to 10 μm) therebetween and equipotential surfaces are likely to densely gather between the trenches 13 in the present embodiment, the breakdown voltage of the trenches 13 is likely to become relatively lower than that in the vicinity of the terminal of the anode electrode 31.

In FIG. 8, experimental results when the trenches 13 are in a stripe shape are shown, but the same effect can be obtained as long as the trenches 13 are in the shape shown in any of FIG. 7A to FIG. 7C or in other cases where the trenches 13 satisfy that the parallel component A is larger than the perpendicular component B.

### <Modifications of Schottky Barrier Diode 1>

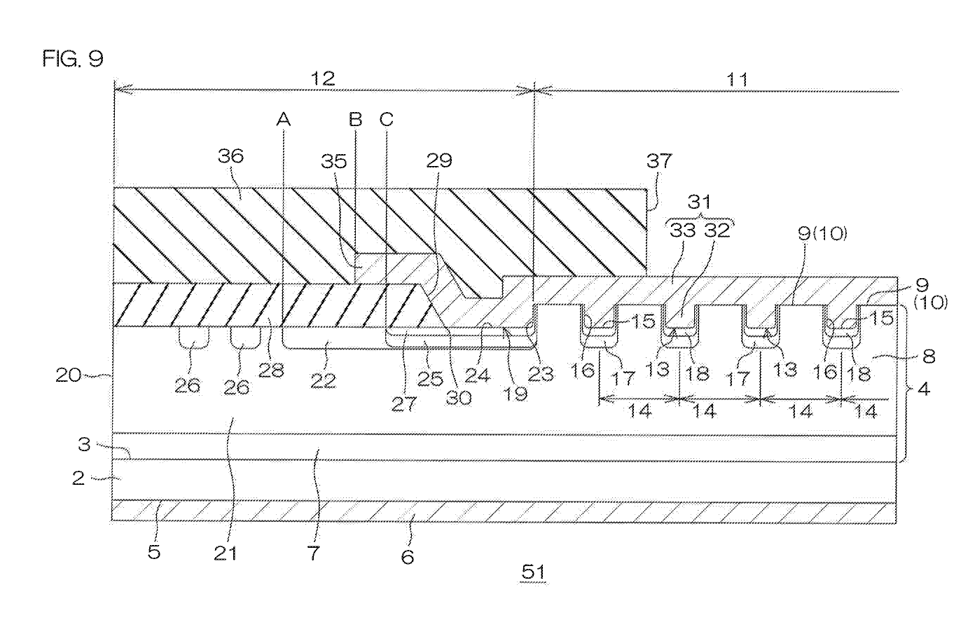

FIG. 9 to FIG. 19 are, respectively, views showing modifications of the Schottky barrier diode 1 of FIG. 3. In FIG. 9 to FIG. 19, the same reference sign is given to components corresponding to each other between FIG. 3 shown above and FIG. 9 to FIG. 19.

First, as in the Schottky barrier diode 51 of FIG. 9, the outer peripheral edge 30 of the contact hole 29 may be set on the side closer to the active region 11 with respect to the p type layer edge C in the configuration of the Schottky barrier diode 1 of FIG. 3.

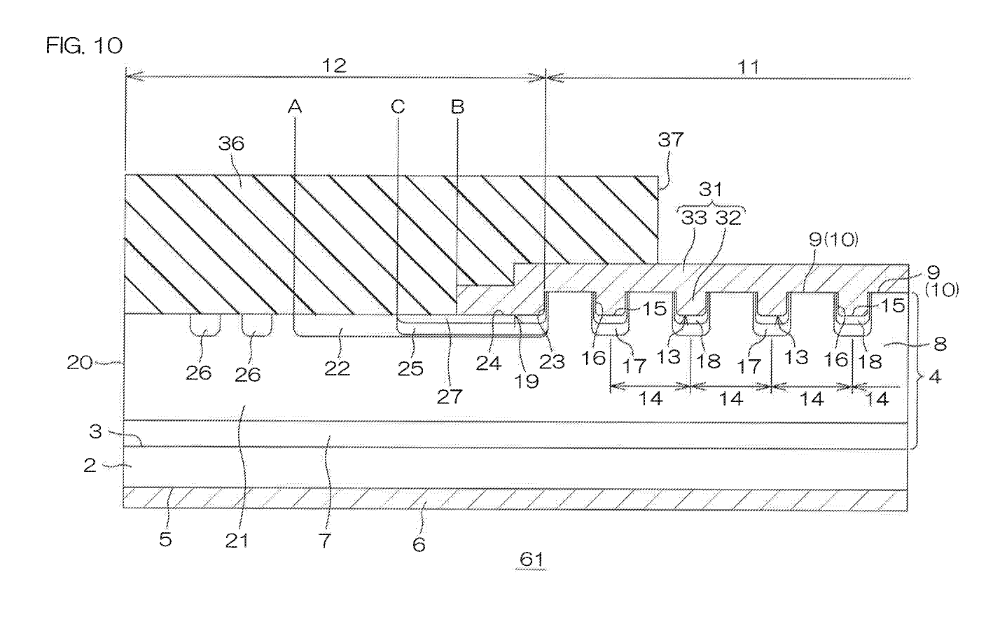

Next, as in the Schottky barrier diode 61 of FIG. 10, the field insulating film 28 may be excluded in the configuration of the Schottky barrier diode 1 of FIG. 3. In this case, the planar portion 33 of the anode electrode 31 is formed so as to be in contact with the side surface 23 and the bottom surface 24 of the removal region 19. The electrode edge B of the planar portion 33 is positioned on the side closer to the active region 11 with respect to the p type layer edge C of the p type layer 25. The surface protection film 36 is formed so as to be in contact with the bottom surface 24 of the removal region 19 exposed from the anode electrode 31.

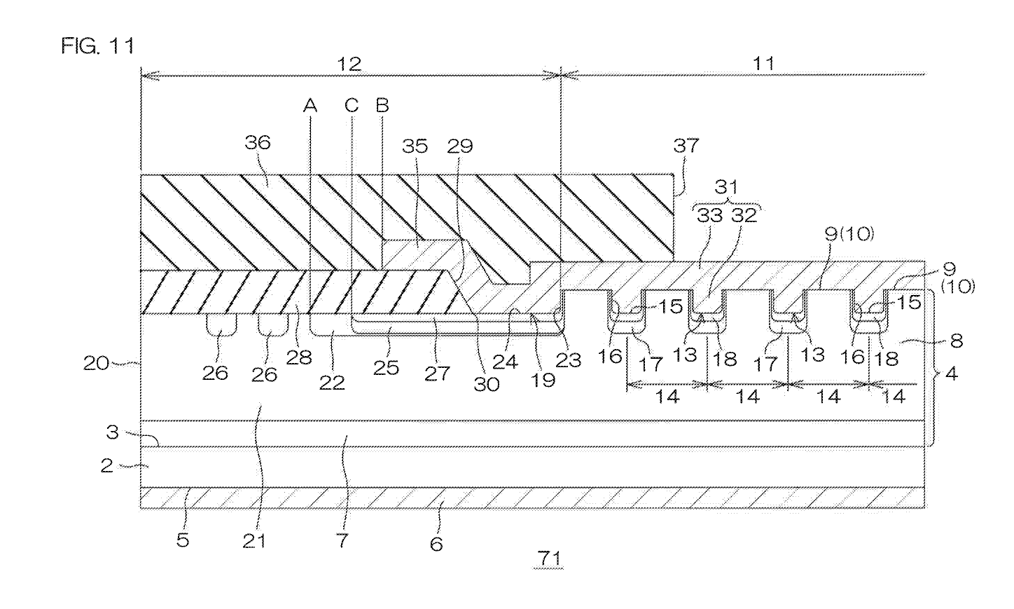

Next, as in the Schottky barrier diode 71 of FIG. 11, the electrode edge B of the planar portion 33 of the anode electrode 31 may be positioned on the side closer to the active region 11 with respect to the p type layer edge C of the p type layer 25 in the configuration of the Schottky barrier diode 1 of FIG. 3. In other words, the overlap portion 35 may be housed in an inner area of the p type layer 25.

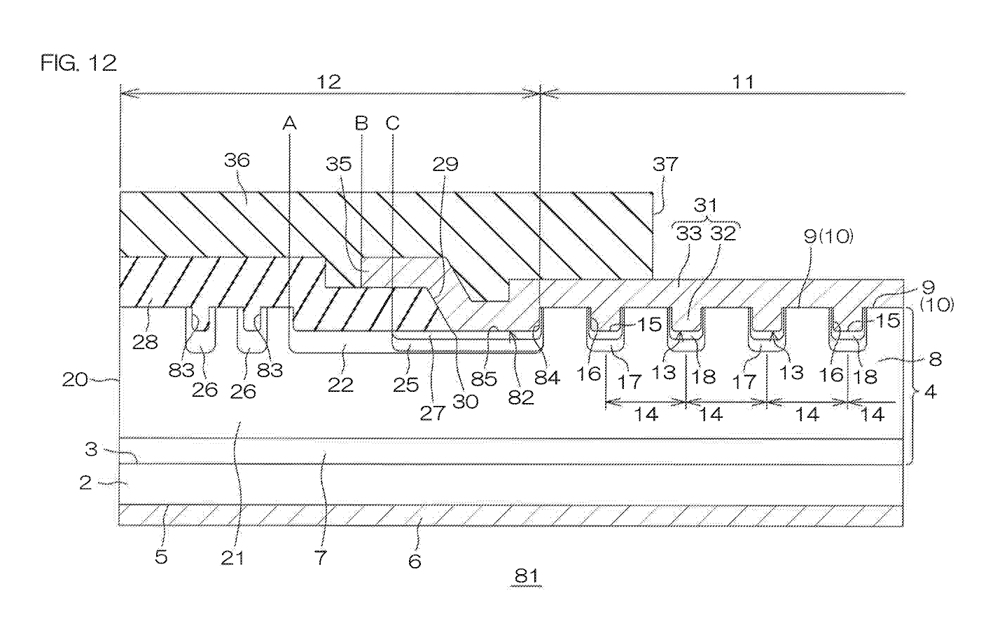

Next, as in the Schottky barrier diode 81 of FIG. 12, a JTE trench 82 and guard ring trenches 83, which are an example of a removal region of the present invention, may be selectively formed, in place of the removal region 19, at a formation position of the p type JTE structure 22 and a formation position of the guard rings 26 in the outer peripheral region 12, respectively, in the configuration of the Schottky barrier diode 1 of FIG. 3.

In this case, the p type JTE structure 22 may be formed so as to follow the inner surface (a side surface 84 and a bottom surface 85) of the JTE trench 82, and the guard ring 26 may be formed so as to follow the inner surface (bottom surface and side surface) of the guard ring trench 83. Although the p type JTE structure 22 and the guard ring 26 are formed at the entire inner surfaces of the trenches 82 and 83, respectively, these may be selectively formed at only a part of the inner surfaces. The field insulating film 28 is formed so as to be embedded in the JTE trench 82 and in the guard ring trenches 83.

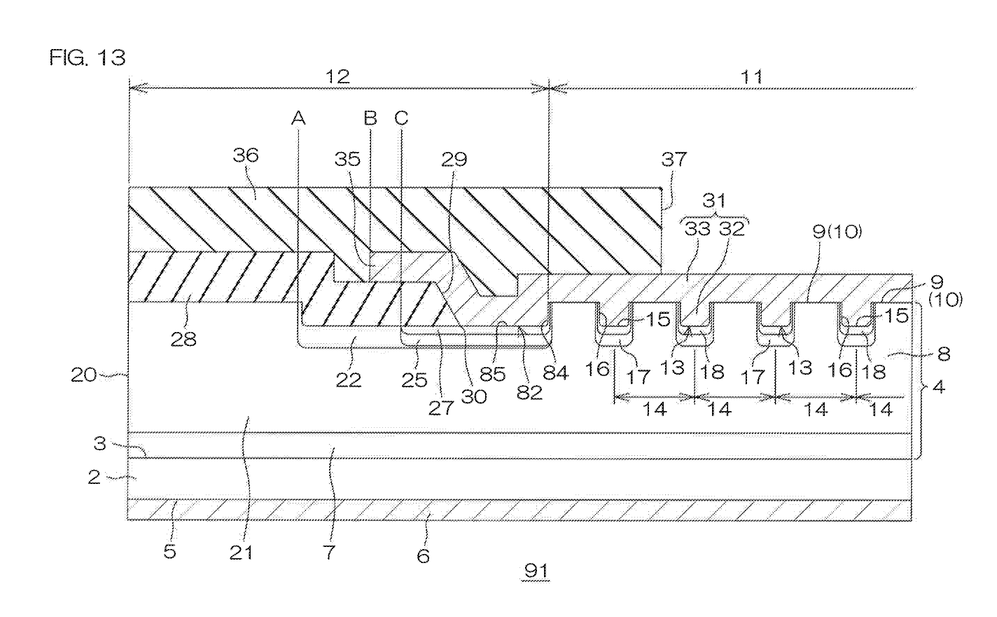

Next, as in the Schottky barrier diode 91 of FIG. 13, the guard ring trenches 83 and the guard rings 26 may be excluded in the configuration of the Schottky barrier diode 81 of FIG. 12.

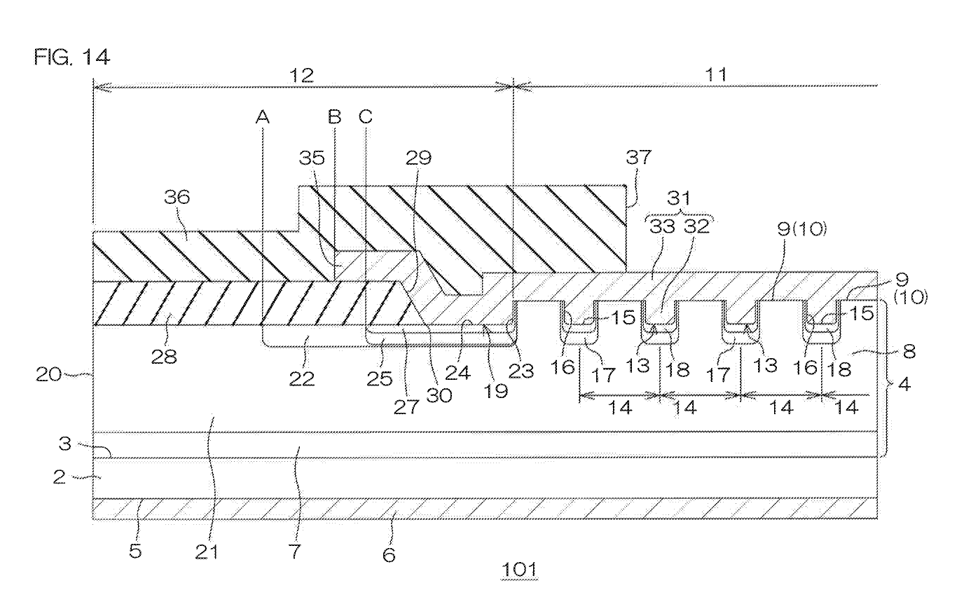

Next, as in the Schottky barrier diode 101 of FIG. 14, the guard rings 26 may be excluded in the configuration of the Schottky barrier diode 1 of FIG. 3.

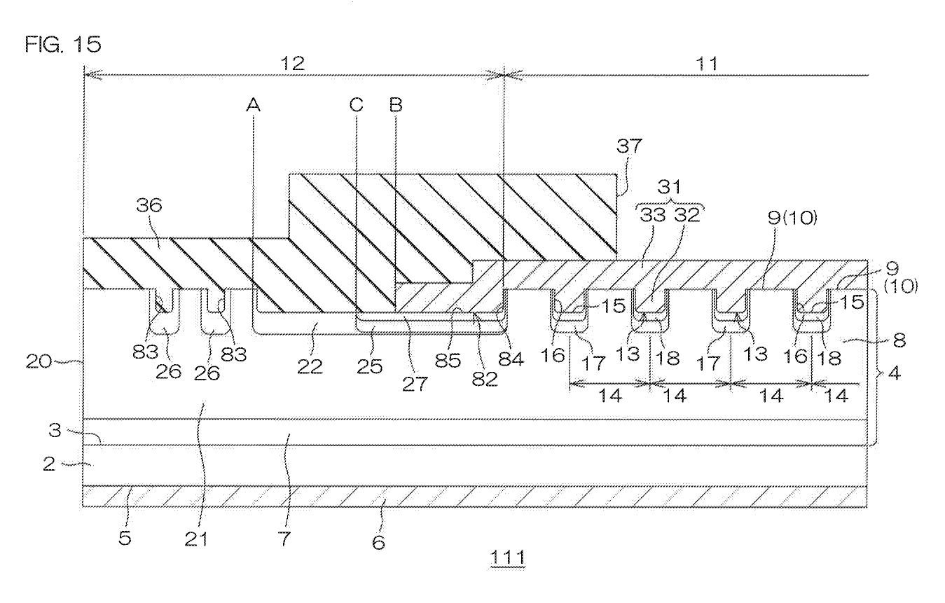

Next, as in the Schottky barrier diode 111 of FIG. 15, the field insulating film 28 may be excluded in the configuration of the Schottky barrier diode 81 of FIG. 12. In this case, the planar portion 33 of the anode electrode 31 may be formed so as to be in contact with the side surface 84 and the bottom surface 85 of the JTE trench 82. The electrode edge B of the planar portion 33 is positioned on the side closer to the active region 11 with respect to the p type layer edge C of the p type layer 25. The surface protection film 36 is formed so as to be in contact with the bottom surface 85 of the JTE trench 82 exposed from the anode electrode 31. The surface protection film 36 is embedded in the guard ring trenches 83.

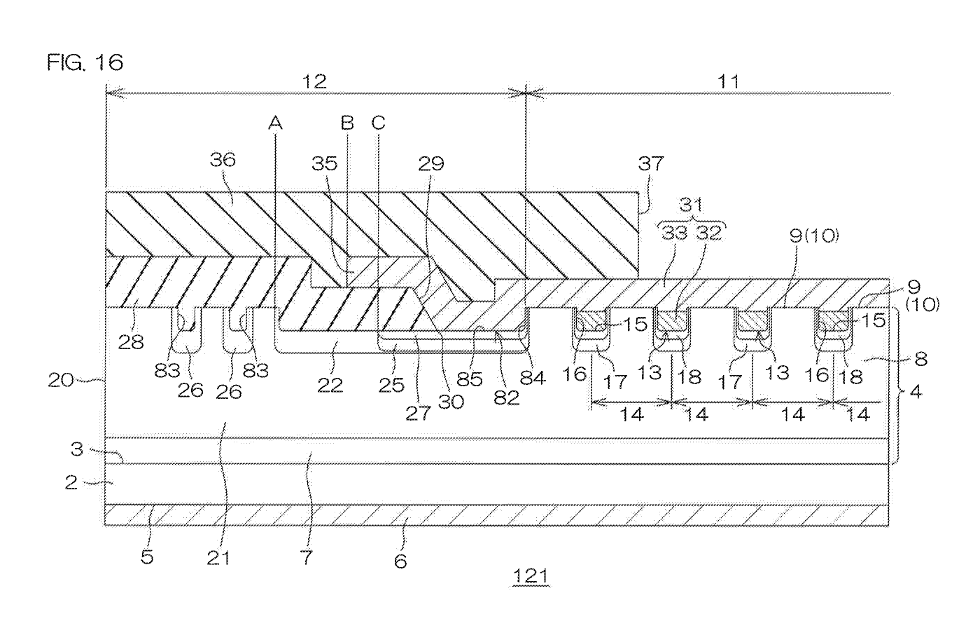

Next, as in the Schottky barrier diode 121 of FIG. 16, the planar portion 33 and the embedded portion 32 may be formed with mutually different materials in the configuration of the Schottky barrier diode 81 of FIG. 12.

As described above, Ti/Al and so forth can be used as the material of the planar portion 33. On the other hand, a material excellent in embedding properties, such as polysilicon (n type or p type doped polysilicon), tungsten (W), titanium (Ti), or an alloy of these elements, can be used as the material of the embedded portion 32.

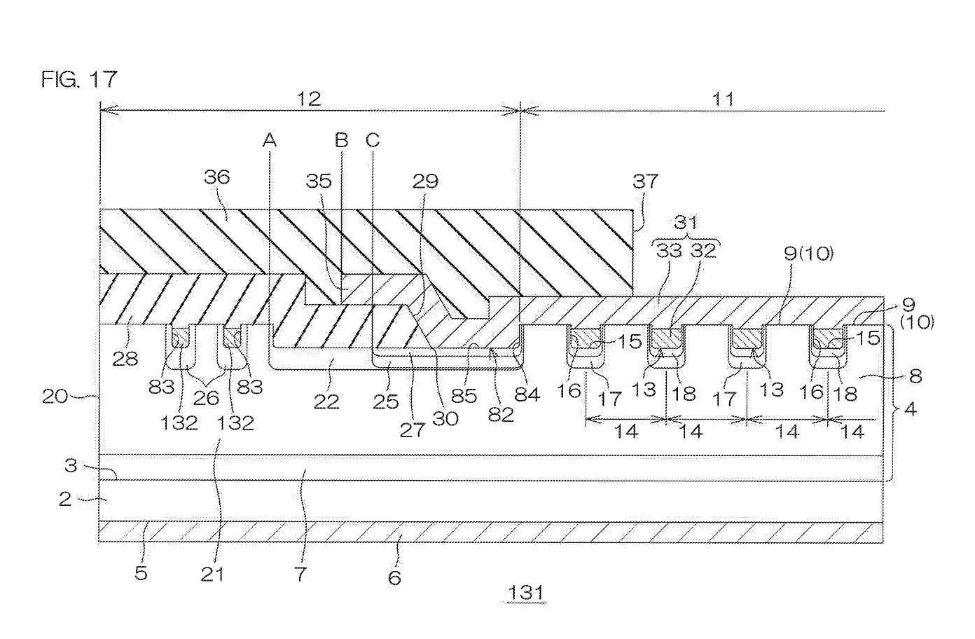

Next, as in the Schottky barrier diode 131 of FIG. 17, a guard-ring embedding layer 132 may be embedded in the guard ring trenches 83 in place of the field insulating film 28 embedded in the guard ring trenches 83 in the configuration of the Schottky barrier diode 121 of FIG. 16.

The same material as the embedded portion 32 of the anode electrode 31 can be used as the material of the guard-ring embedding layer 132. This makes it possible to simultaneously form the guard-ring embedding layer 132 and the embedded portion 32 of the anode electrode 31.

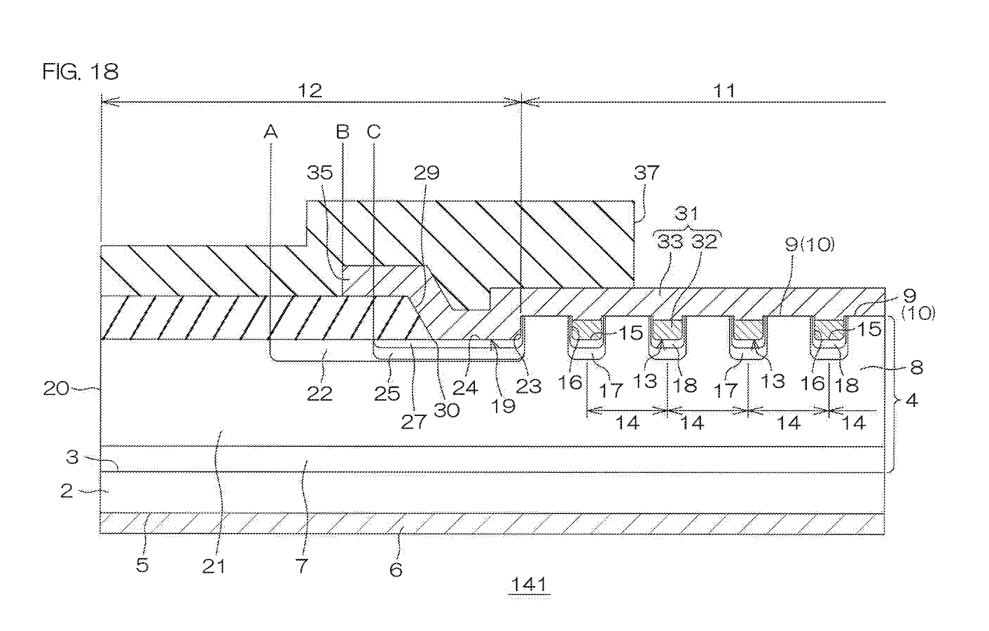

Next, as in the Schottky barrier diode 141 of FIG. 18, the planar portion 33 and the embedded portion 32 may be formed with mutually different materials in the configuration of the Schottky barrier diode 1 of FIG. 3.

As described above, Ti/Al and so forth can be used as the material of the planar portion 33. On the other hand, a material excellent in embedding properties, such as polysilicon (n type or p type doped polysilicon), tungsten (W), titanium (Ti), or an alloy of these elements, can be used as the material of the embedded portion 32.

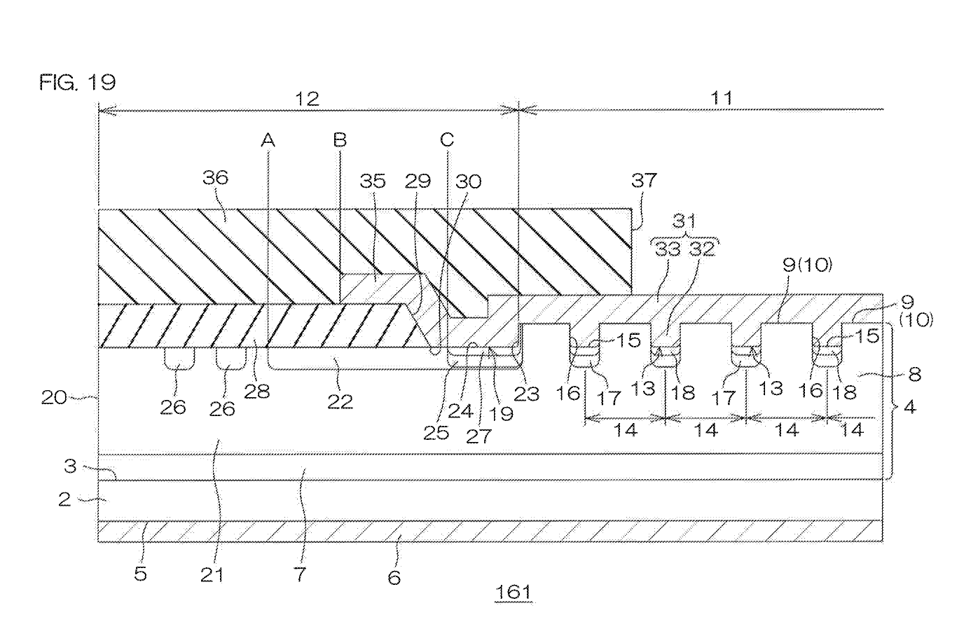

Next, as in the Schottky barrier diode 161 of FIG. 19, the p type layer 17 and the p⁺ type contact layer 18 may be selectively formed at only the bottom surface 15 of the trench 13 in the configuration of the Schottky barrier diode 1 of FIG. 3. As a result, an n type region of the n⁻ type drift layer 8 may be exposed to the side surface 16 of the trench 13.

Next, a method for forming the p type layers 17, 18, 22, and 25 to 27 of the Schottky barrier diodes will be described separately into the case of the Schottky barrier diodes 81, 91, 111, 121, and 131 each of which has the JTE trench 82 and the guard ring trenches 83 and the case of the Schottky barrier diodes 1, 51, 61, 71, and 141 each of which has the removal region 19.

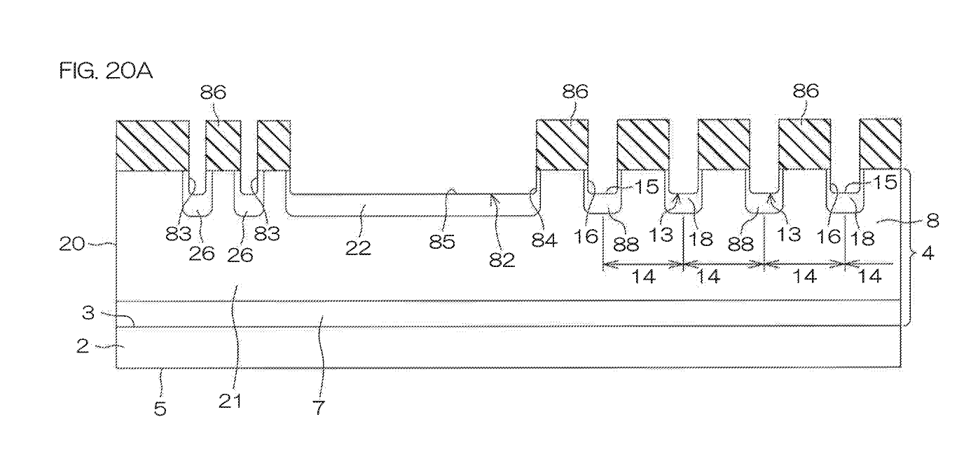

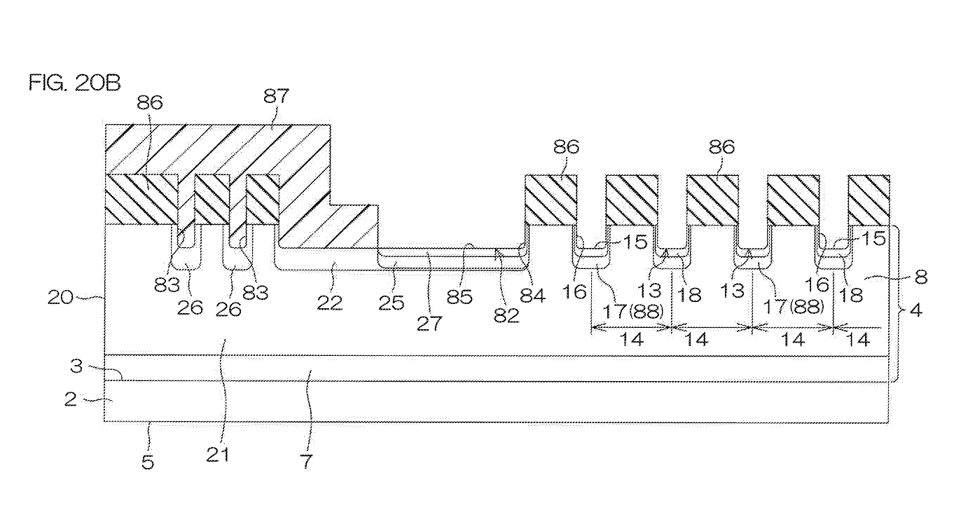

First, the former, i.e., the case of the Schottky barrier diodes 81, 91, 111, 121, and 131 will be described with reference to FIG. 20A and FIG. 20B.

As shown in FIG. 20A, a hard mask 86 that has openings according to the patterns of the trenches 13, of the JTE trench 82, and of the guard ring trenches 83 is formed, and the trenches 13, the JTE trench 82, and the guard ring trenches 83 are formed by an etching operation that uses the hard mask 86, and, simultaneously, unit cells 14 defined by the trenches 13 are formed.

Thereafter, in a state in which the hard mask 86 remains, impurities (in the present embodiment, Al ions) are selectively implanted into the inner surfaces of the trenches 13, of the JTE trench 82, and of the guard ring trenches 83. As a result, a p type JTE structure 22, guard rings 26, and a p type layer 88 having the same shape as that of the p type layer 17 are simultaneously formed.

Thereafter, as shown in FIG. 20B, a resist mask 87 with which the p type JTE structure 22 and the guard rings 26 are selectively covered is formed. Thereafter, in a state in which this resist mask 87 and the hard mask 86 remain, impurities (in the present embodiment, Al ions) are selectively implanted into the inner surfaces of the trenches 13 and of the JTE trench 82. As a result, p type layers 17, 25 and p⁺ type contact layers 18, 27, which are relatively higher in concentration than the p type JTE structure 22 and the guard rings 26, are simultaneously formed.

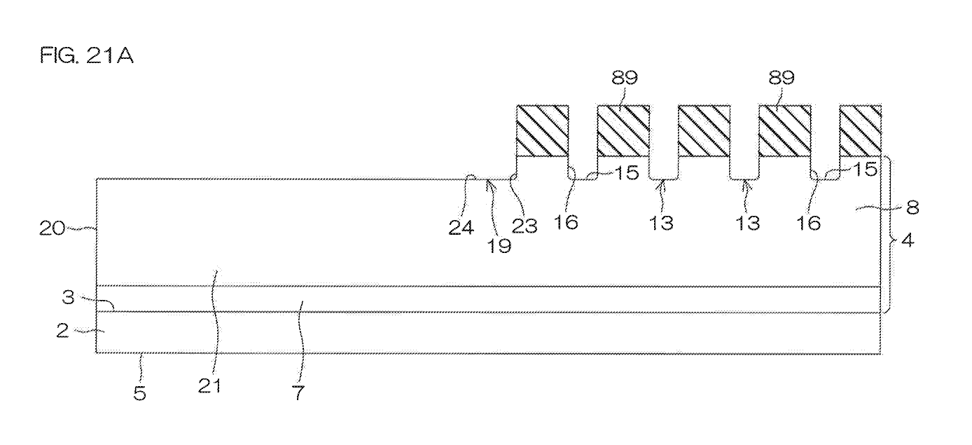

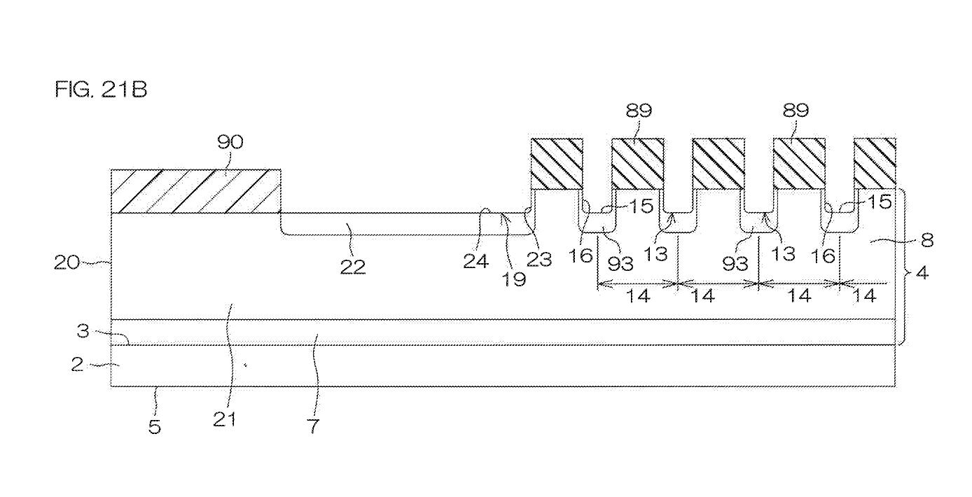

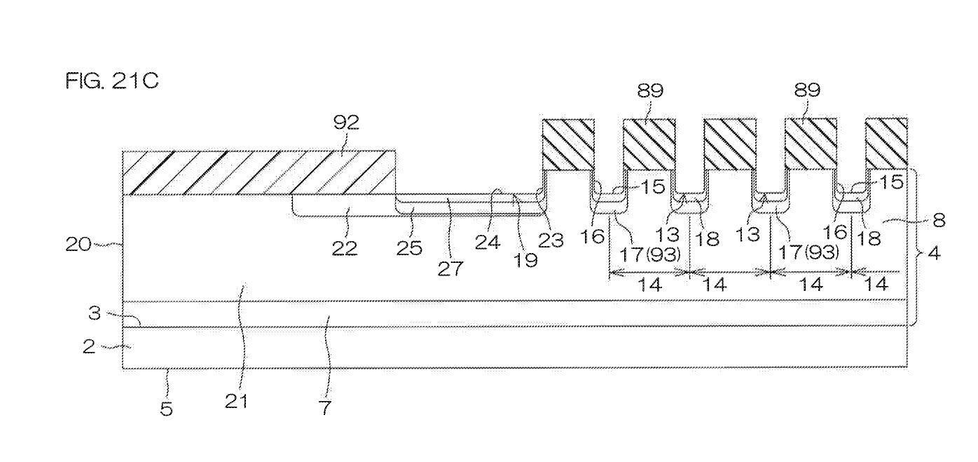

Next, the latter, i.e., the case of the Schottky barrier diodes 1, 51, 61, 71, and 141 will be described with reference to FIG. 21A to FIG. 21C.

As shown in FIG. 21A, a hard mask 89 that has openings according to the patterns of the trenches 13 and of the removal region 19 is formed, and the trenches 13 and the removal region 19 are formed by an etching operation that uses this hard mask 89, and, simultaneously, unit cells 14 defined by the trenches 13 are formed.

Thereafter, as shown in FIG. 21B, in a state in which the hard mask 89 remains, a resist mask 90 that has an opening according to the pattern of the p type JTE structure 22 in the removal region 19 is formed. Thereafter, impurities (in the present embodiment, Al ions) are selectively implanted into the inner surfaces of the trenches 13 and of the removal region 19 by use of the hard mask 89 and the resist mask 90. As a result, a p type JTE structure 22 and a p type layer 93 having the same shape as that of the p type layer 17 are simultaneously formed.

Thereafter, as shown in FIG. 21C, a resist mask 92 with which the p type JTE structure 22 is selectively covered is formed. Thereafter, in a state in which this resist mask 92 and the hard mask 89 remain, impurities (in the present embodiment, Al ions) are selectively implanted into the inner surfaces of the trenches 13 and of the JTE trench 82. As a result, p type layers 17, 25 and p⁺ type contact layers 18, 27, which are relatively higher in concentration than the p type JTE structure 22, are simultaneously formed.

### <Configuration of Field Effect Transistor 151>

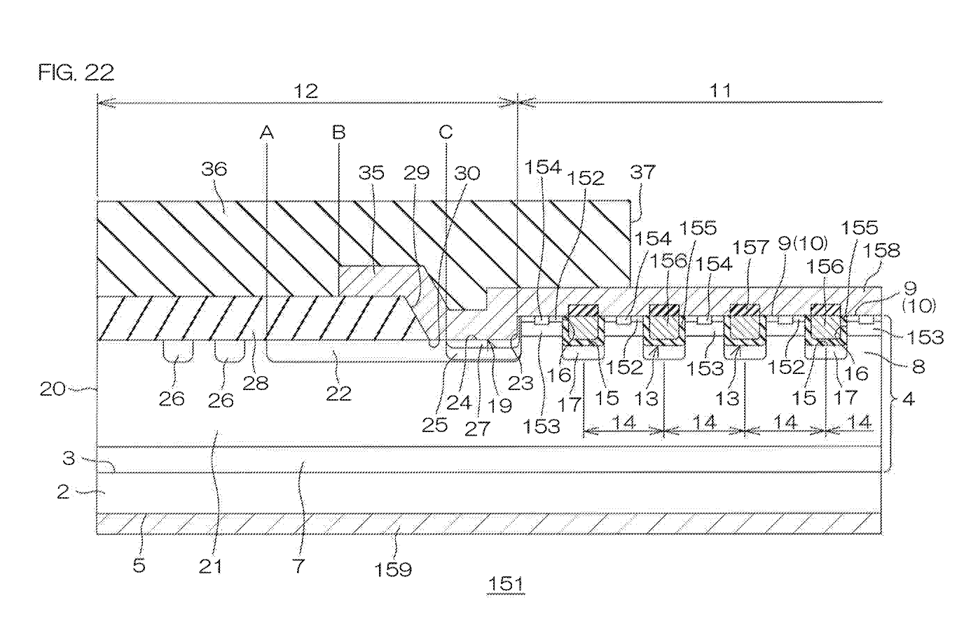

FIG. 22 is a schematic cross-sectional view of a field effect transistor 151 according to an embodiment of the present invention. In FIG. 22, the same reference sign is given to components corresponding to each other between FIG. 3 shown above and FIG. 22.

In the field effect transistor 151 of FIG. 22, an n⁺ type source region 152 that is exposed to the surface 10 of the epitaxial layer 4 so as to form a part of the side surface 16 of the trench 13 and a p type channel region 153 adjacent at the back surface side of the n⁺ type source region 152 so as to form a part of the side surface 16 of the trench 13 are formed in each unit cell 14. Additionally, a p⁺ type channel contact region 154 that penetrates through the n⁺ type source region 152 to reach the p type channel region 153 from the surface 10 is formed. In this field effect transistor 151, the n⁻ type drift layer 8 serves as a drain region. In the trenches 13, a gate electrode 156 is embedded via a gate insulating film 155.

The p type layer 17 is formed, of the bottom surface and the side surface 16 of each trench 13, selectively at the bottom surface 15.

Additionally, at the surface 10 of the epitaxial layer 4, an interlayer insulating film 157 formed with an opening to selectively expose the n⁺ type source region 152 is formed, and a source electrode 158 that is an example of a first electrode of the present invention forms an ohmic contact between the n⁺ source region 152 and the source electrode 158 through that opening. On the other hand, at the back surface 5 of the n⁺ type substrate 2, a drain electrode 159 that is an example of a second electrode of the present invention and that forms an ohmic contact between the n⁺ type substrate 2 and the drain electrode 159 is formed.

This field effect transistor 151 also makes it possible to achieve the same effect of an improvement in breakdown voltage as with the Schottky barrier diode 1.

Similar to that the modifications shown in FIG. 9 to FIG. 19 can be applied to the Schottky barrier diode 1 of FIG. 3, modifications the same as the configurations shown in FIG. 9 to FIG. 19 can also be applied to the field effect transistor 151 of FIG. 22. For example, in the configuration of the field effect transistor 151 of FIG. 22, the outer peripheral edge 30 of the contact hole 29 may be set on the side closer to the active region 11 with respect to the p type layer edge C as shown in FIG. 9.

Although the embodiments of the present invention have been described as above, the present invention can be embodied in other modes.

For example, it is possible to combine the aforementioned features comprehended from the disclosure of the embodiments and modifications described above together among embodiments and modifications shown by different figures.

Additionally, the off-direction of the n⁺ type substrate 2 may be the direction of the [1-100] axis. Further, the surface 3 (principal plane) of the n⁺ type substrate 2 may be the C plane. When the C plane is used, preferably, the off-angle of the n⁺ type substrate 2 is 0.6° or more (preferably, 10° or less) from the viewpoint of an improvement in controllability in epitaxial growth.

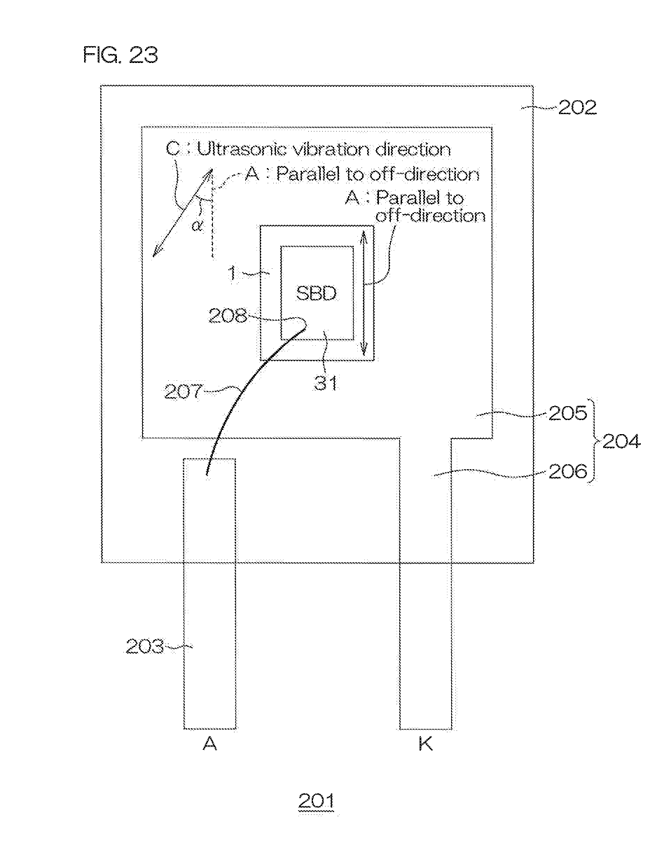

Additionally, C: ultrasonic vibration direction when the bonding wire 207 is bonded to the Schottky barrier diode 1 is not necessarily A: parallel to the off-direction as shown in FIG. 1. For example, C: ultrasonic vibration direction may be A: parallel to the off-direction and substantially parallel to the off-direction. Specifically, it is preferable that C: ultrasonic vibration direction is parallel to the extending direction of the bonding wire 207 and the angle α created by A: parallel to the off-direction and C: ultrasonic vibration direction is 30° or less as shown in FIG. 23, and more preferably, the angle α is 15° or less.

Additionally, an arrangement formed by reversing the conductivity type in each semiconductor part of the Schottky barrier diode 1 and the field effect transistor 151 described above may be employed. For example, in the Schottky barrier diode 1, the p type part may be an n type, and the n type part may be a p type.

The semiconductor device (semiconductor power device) of the present invention is capable of being incorporated into a power module for use in an inverter circuit forming a driving circuit to drive an electric motor that is used as a power source of, for example, an electric automobile (including a hybrid automobile), a train, and an industrial robot. Additionally, the semiconductor device of the present invention is also capable of being incorporated into a power module for use in an inverter circuit that converts electric power generated by a solar battery, by a wind generator, or by other power generators (particularly, a private electric generator) so as to match the electric power of a commercial power source.

The embodiments of the present invention are merely concrete examples used to clarify the technical contents of the present invention, and the present invention should not be understood by being limited to these concrete examples, and the spirit and scope of the present invention are limited solely by the appended claims. The present application corresponds to Japanese Patent Application No. 2013-221532 filed in the Japan Patent Office on Oct. 24, 2013, and the entire disclosure of this application is incorporated herein by reference.

### REFERENCE SIGNS LIST

1 Schottky barrier diode
2 n⁺ type substrate
4 Epitaxial layer
6 Cathode electrode
7 n type buffer layer
8 n⁻ type drift layer
9 (Unit cell) Upper surface
10 (Epitaxial layer) Surface
11 Active region
12 Outer peripheral region
13 Trench
16 (Trench) Side surface
19 Removal region
20 (Epitaxial layer) End surface
22 p type JTE structure
24 (Removal region) Bottom surface
25 p type layer
26 Guard ring
27 p⁺ type contact layer
28 Field insulating film
29 Contact hole
31 Anode electrode
51 Schottky barrier diode
61 Schottky barrier diode
71 Schottky barrier diode
81 Schottky barrier diode
82 JTE trench
83 Guard ring trench
85 (Trench) Bottom surface
91 Schottky barrier diode
101 Schottky barrier diode
111 Schottky barrier diode
121 Schottky barrier diode
131 Schottky barrier diode
141 Schottky barrier diode
151 Field effect transistor
152 n⁺ type source region
153 p type channel region
155 Gate insulating film
156 Gate electrode
158 Source electrode
159 Drain electrode
161 Schottky barrier diode
A JTE edge
B Electrode edge
C p type layer edge

1. A semiconductor device comprising:
a semiconductor layer that has an off-angle inclined in a predetermined off-direction and that is made of a first conductivity type wide bandgap semiconductor at a surface of which a trench is formed;
a first electrode bonded to a surface of the semiconductor layer; and
a second electrode bonded to a back surface of the semiconductor layer,
wherein, when a side surface of the trench is decomposed into a parallel component and a perpendicular component with respect to the off-direction of the semiconductor layer, the parallel component is larger than the perpendicular component.

2. The semiconductor device according to claim 1, wherein the semiconductor layer has an off-angle of 0.1° to 10°.

3. The semiconductor device according to claim 2, wherein the semiconductor layer is made of 4H—SiC having the surface being a Si plane and has an off-angle of 2° or more.

4. The semiconductor device according to claim 2, wherein the semiconductor layer is made of 4H—SiC having the surface being a C plane and has an off-angle of 0.6° or more.

5. The semiconductor device according to claim 1, wherein the off-direction is a [11-20] axis direction or a [1-100] axis direction.

6. The semiconductor device according to claim 1, wherein the trench is formed in a stripe shape extending in a direction parallel to the off-direction.

7. The semiconductor device according to claim 1, comprising a second conductivity type terminal structure formed at a surface of the semiconductor layer adjacent to a terminal of the first electrode.

8. The semiconductor device according to claim 7, wherein the semiconductor layer includes an active region and an outer peripheral region that surrounds the active region and that is formed with a removal region in a surface portion of the semiconductor layer, and
the terminal structure is formed along a bottom surface of the removal region.

9. The semiconductor device according to claim 7, further comprising a second conductivity type layer that is formed in an inner area of the terminal structure and that is higher in concentration than the terminal structure.

10. The semiconductor device according to claim 9, wherein the second conductivity type layer includes a highly-concentrated region that is formed so as to be exposed to the surface of the semiconductor layer and that is higher in concentration than the second conductivity type layer.

11. The semiconductor device according to claim 9, wherein an edge of the terminal structure, an edge of the first electrode, and an edge of the second conductivity type layer are disposed in this order from an end surface of the semiconductor layer.

12. The semiconductor device according to claim 7, further comprising a second conductivity type guard ring formed on an outer side toward an end surface of the semiconductor layer with respect to the terminal structure.

13. The semiconductor device according to claim 7, comprising a field insulating film formed from an edge of the terminal structure so as to selectively cover the terminal structure.

14. The semiconductor device according to claim 13, wherein a contact hole for the first electrode joining the surface of the semiconductor layer is formed in the field insulating film, and
the contact hole is formed in a tapered shape whose width becomes wider toward an opening end.

15. The semiconductor device according to claim 1, wherein the trench is formed as a plurality of mutually spaced trenches when the semiconductor layer is viewed cross-sectionally, and
the plurality of trenches adjoining each other have a spacing of 0.1 μm to 10 μm therebetween.

16. The semiconductor device according to claim 1, wherein the semiconductor device includes a Schottky barrier diode for which the first electrode forms a Schottky junction between the surface of the semiconductor layer and the first electrode, and the second electrode forms an ohmic contact between the back surface of the semiconductor layer and the second electrode.

17. The semiconductor device according to claim 1, comprising:
a first conductivity type source region that is exposed to the surface of the semiconductor layer so as to form a part of the side surface of the trench;
a second conductivity type channel region that is adjacent at a back surface side of the source region so as to form a part of the side surface of the trench;
a first conductivity type drain region that is adjacent at a back surface side of the channel region so as to form a bottom surface of the trench; and
a gate electrode that is embedded in the trench via a gate insulating film,
wherein the semiconductor device includes a field effect transistor for which the first electrode forms an ohmic contact between the source region and the first electrode, and the second electrode forms an ohmic contact between the drain region and the second electrode.

18. A semiconductor package comprising:
the semiconductor device according to claim 1;
a first terminal connected to the first electrode of the semiconductor device via a bonding wire;
a second terminal on which the semiconductor device is die-bonded and which is connected to the second electrode; and
a resin package that encapsulates the semiconductor device, the first terminal, and the second terminal,
wherein the bonding wire is bonded to the first electrode by applying ultrasonic vibration along a predetermined ultrasonic vibration direction, and
the off-direction and the ultrasonic vibration direction create an angle of 30° or less therebetween.

19. The semiconductor package according to claim 18, wherein the off-direction and the ultrasonic vibration direction are parallel to each other.
